(19) United States
(12) Patent Application Publication
(10) Pub. No.: US 2008/0011996 A1
(43) Pub. Date: Jan. 17, 2008

(54) MULTI-LAYER DEVICE WITH SWITCHABLE RESISTANCE

(76) Inventors: Johannes Georg Bednorz, Wolfhausen (CH); Walter Heinrich Riess, Thalwil (CH); Siegfried F. Karg, Adliswil (CH); Gerhard Ingmar Meijer, Zurich (CH); German Hammerl, Augsburg (DE)

Correspondence Address: IBM CORPORATION, T.J. WATSON RESEARCH CENTER, P.O. BOX 218, YORKTOWN HEIGHTS, NY, 10598, US

(21) Appl. No.: 11/456,591

(22) Filed: Jul. 11, 2006

(51) Int. Cl. H01L 29/02

(52) U.S. Cl. 257/2

(57) ABSTRACT

The present invention provides a microelectronic device comprising a resistance structure including a plurality of programmable resistance layers and at least one intermediate layer such that an intermediate layer is placed between two programmable resistance layers. The programmable resistance layers can be individually doped or may consist of different materials. Each programmable resistance layer may be optimized for a specific application. The microelectronic device can be used as a programmable resistor or a memory cell as it exhibits switchable electrical resistance and does not require a time-consuming conditioning process.

### FIELD OF THE INVENTION

The present invention relates to a multi-layer device with switchable resistance. More particularly, the present invention relates to a microelectronic device having switchable electrical resistance.

### BACKGROUND

The use of materials with programmable electrical resistance for semiconductor device applications is known in the art. Semiconductor devices for example, microelectronic devices, employ materials, including but not limited to transition-metal oxide materials, with programmable electrical resistance. The electrical resistance of the materials can be changed significantly by varying external influences, including temperature, magnetic fields and electric fields. Electrical impulses applied to these materials can program their electrical resistance, such that they exhibit a desired resistive property.

FIG. 1 depicts a microelectronic device 100 known in the art. Device 100 includes a first electrode 102, a second electrode 104 and a dielectric layer 106. Dielectric layer 106 is sandwiched between first electrode 102 and second electrode 104. Dielectric layer 106 is made from an insulating dielectric material, for example, a transition-metal oxide, which can be conditioned such that it exhibits desired bi-stable electrical resistance. The transition-metal oxide can be conditioned using a known technique, for example, by exposing the transition-metal oxide to an electrical signal, an electric field, a magnetic field and the like.

FIG. 2 depicts microelectronic device 100 (illustrated in FIG. 1) after a conditioning process. The conditioning process includes subjecting dielectric layer 106 to an appropriate electrical signal, which is one of the many ways of conditioning listed above, for a period of time. The conditioning process generates a confined conductive region 202 of arbitrary shape in dielectric layer 106. The interfaces of confined conductive region 202 to electrodes 102 and 104 are of high resistivity and can be reversibly switched between multiple resistance states.

Confined conductive region 202 is generated at an arbitrary position in dielectric layer 106, i.e., the position of the conducting path is not controlled by process parameters.

A known microelectronic device with switching electrical resistance known in the art is designed such that it includes a region between electrodes having a switchable electrical resistance wherein the region is made of a substance comprising components Aₓ, B_{y}, and oxygen O_{z}. The electrical resistance in the region is reversibly switchable between different states by applying different voltage pulses. The different voltage pulses lead to the respective different states. An appropriate amount of dopant(s) in the substance improves the switching, whereby the microelectronic device becomes controllable and reliable.

Another known microelectronic device describes a switchable resistive device having a multi-layer thin film structure interposed between an upper conductive electrode and a lower conductive electrode. The multi-layer thin film structure includes a perovskite layer with one buffer layer on one side of the perovskite layer, or a perovskite layer with buffer layers on both sides of the perovskite layer. Reversible resistance changes are induced in the device under applied electrical pulses. The resistance changes of the device are retained after applied electric pulses. The functions of the buffer layer(s) added to the device include magnification of the resistance switching region, reduction of the pulse voltage needed to switch the device, protection of the device from being damaged by a large pulse shock, improvement of the temperature and radiation properties, and increased stability of the device allowing for multi-valued memory applications.

However, the perovskite layer has to be conditioned such that it exhibits the desired bi-stable electrical resistance. The conditioning process generates a confined conductive region at an arbitrary position in the dielectric material. This leads to a large variation in the electrical properties of nominally identical memory cells made of the aforesaid microelectronic devices and conventional programmable resistors. Moreover, only a part of the area defined by the electrodes is used for current flow. Hence, the confined region is subject to local heating and, hence, to potential damage.

Thus there is a need for an improved microelectronic device having programmable resistance and a method for fabricating the same.

### SUMMARY

In accordance with an aspect of the present invention, a microelectronic device and a method of manufacturing same is provided. One embodiment of the microelectronic device comprises a first electrode, a second electrode facing the first electrode and several programmable resistance layers placed between the first electrode and the second electrode. The microelectronic device further includes at least one intermediate layer such that the intermediate layer is placed between two programmable resistance layers. Further, the resistivity of the intermediate layer is between the low resistivity of the first and second electrodes and the high resistivity of the programmable resistance layers.

### BRIEF DESCRIPTION OF DRAWINGS

The above and other items, features and advantages of the invention will be better understood by reading the following more particular description of the invention in conjunction with the accompanying drawings wherein:

FIG. 1 depicts schematic of a prior art microelectronic device having a programmable resistive layer.

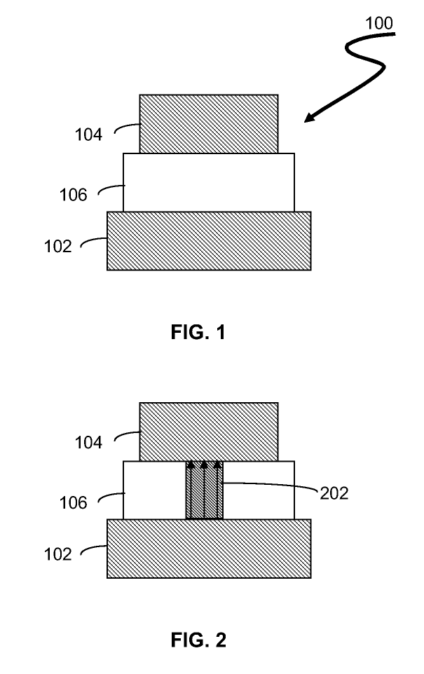

FIG. 2 illustrates a conduction region in the device of FIG. 1 after a conditioning process in accordance with a prior art.

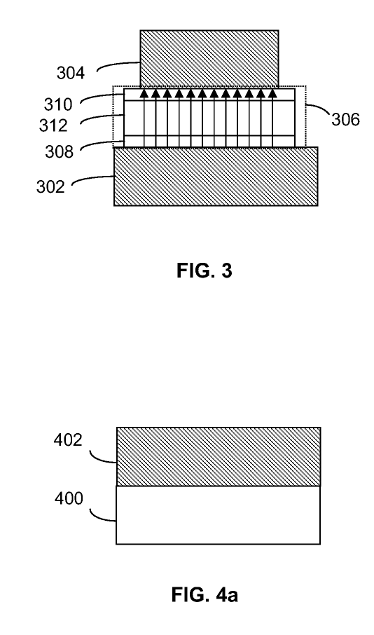

FIG. 3 illustrates a microelectronic device in accordance with an embodiment of the present invention.

FIGS. 4a to 4e illustrate cross-sections of the microelectronic device during the fabrication process in accordance with an embodiment of the present invention.

FIG. 5 shows a flowchart illustrating the steps of a method for fabricating the microelectronic device in accordance with an embodiment of the present invention.

### DETAILED DESCRIPTION

The present invention provides a microelectronic device including a plurality of programmable resistance layers and at least one intermediate layer such that an intermediate layer is present between two programmable resistance layers. The programmable resistance layers are made of material that exhibit bi-stable resistance while the intermediate layers are made of material that is electrically conducting. The resistivity of the intermediate layer varies between the low resistivity of electrodes and high resistivity of the programmable resistance layers thereby allowing current flow defined by electrodes. The programmable resistance layers can be individually doped or may consist of different materials. Each programmable resistance layer may be optimized for a specific application.

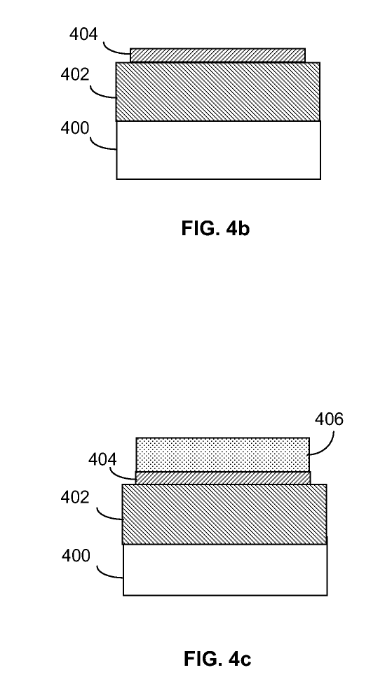

FIG. 3 illustrates a microelectronic device 300 in accordance with an embodiment of the present invention. Microelectronic device 300 includes a first electrode 302, a second electrode 304 facing the first electrode 302, and a resistance structure 306 between first electrode 302 and second electrode 304. In one embodiment of the invention, the first and second electrodes are in a spaced apart parallel orientation, where the space between the electrodes is occupied by the resistance structure 306.

In the embodiment, resistance structure 306 includes a first and second programmable resistance layers 308 and 310 placed on top and bottom of an intermediate layer 312. Programmable resistance layers 308 and 310 are made of materials that exhibit a bi-stable electrical resistance. The material used for one programmable resistance layer 308 and 310 can be different from the material used for the other programmable resistance layers. The material can have a composition different from the other programmable resistance layers or can have different doping concentrations. For example, a bi-layer microelectronic device can be fabricated using a sequence of highly doped programmable resistance layer suitable for short forming time and low-doped programmable resistance layer suitable for reliable resistance switching. A person skilled in the art will appreciate that resistance structure 306 may include a plurality of programmable resistance layers such that an intermediate layer is placed between two programmable resistance layers. At least one programmable resistance layer can be customized for a specific application.

In an embodiment, the material used for programmable resistance layers 308 and 310 can be a transition-metal oxide. The transition-metal oxide can be, for example, chromium-doped strontium titanium oxide (Cr-doped SrTiO₃), strontium titanium oxide (SrTiO₃), barium titanium oxide (BaTiO₃), strontium barium titanium oxide ((Sr, Ba)TiO₃), praseodymium manganese oxide (PrMnO₃), calcium manganese oxide (CaMnO₃), praseodymium calcium manganese oxide ((Pr, Ca)MnO₃), strontium zirconium oxide (SrZrO₃), nickel oxide (NiO), titanium oxide (TiO₂), tantalum oxide (Ta₂O₅), and other transition-metal oxides. The transition-metal oxides can be doped with one or more materials such as chromium, manganese, or vanadium. It will be apparent to a person skilled in the art that the present invention is not restricted to the use of aforesaid materials in the formation of the programmable resistance layers. The resistivity of the material of at least one programmable resistance layer is at least 10⁵ Ohm cm initially.

Intermediate layer 312 is made of a material that is electrically conducting and is characterized by a resistivity that is between the low (metallic) resistivity of electrodes 302 and 304 and the high resistivity (insulator) of programmable resistance layers 308 and 310. This enables a current to flow through the entire area defined by electrodes 302 and 304, reducing local heating, and requiring lower driving voltage for a given amount of current. The presence of intermediate layer 312 eliminates the time-consuming conditioning process of programmable resistance layers 308 and 310 and concomitantly reduces variation of the properties of nominally identical microelectronic devices. These microelectronic devices may constitute programmable resistors used in memory cells and devices comprising such memory cells. The electrical pulses used to program the memory cells do not modify the properties, in particular, resistance of intermediate layer 312.

In the embodiment, intermediate layer 312 can be made of a transition-metal oxide, for example, reduced strontium titanium oxide (SrTiO_{3-δ}), niobium-doped strontium titanium oxide (Nb-doped SrTiO₃), lanthanum titanium oxide (LaTiO_{3+δ}), lanthanum strontium titanium oxide ((La, Sr)TiO₃), tin oxide (SnO₂), indium tin oxide (ITO), and other transition-metal oxides with a resistivity between 10⁵ Ohm cm and 0.1 mOhm cm. A person skilled in the art will appreciate that the intermediate layer can be made from materials having a resistance similar to a transition-metal oxide. Examples of such materials include nitrides such as TiN, AlN, and the like.

First electrode 302 and second electrode 304 can be made from conventional electrode materials known in the art. For example, first electrode 302 and second electrode 304 can be conductive film layers. Material of the conductive film layer can be metal, alloy, conductive oxide, or other conductive materials, or their combination, e.g., Pt, Cu, Rh, Pd, Ta, Nb, Ni, W, Mo, Ta, RuO₂, SrRuO₃, IrO₂, YBa₂Cu₃0₇₋ₓ (YBCO), La₁₋ₓSrₓCoO₃ (LSCO), SiC, carbon nano-tube, or their combinations. First electrode 302 is deposited on a substrate, e.g., LaAlO₃ (LAO), SrTiO₃ (STO), MgO, Si, GaAs, TiN, etc., with or without the pre-existence of circuits on the substrate. The first electrode contact pad and second electrode contact pad may be made of metal, conductive compounds and their combination, such as Ag, Au, Pt, Al, Cu, Rh, Pd, Ta, Nb, Ni, W, Mo, Ta, C, or other metal or alloy or a conducting oxide, and may be deposited by any variety of techniques onto first electrode 302 and second electrode 304 respectively.

In accordance with one embodiment of the present invention, the microelectronic device described in FIG. 3 can be used as a memory cell for stable storage of information due to switchable resistance of programmable resistance layers. Fast read, write and erase processes are achievable. The information can be stored by associating a logic state to a value of the resistance of programmable resistance layers, for example, by associating a high resistance state with a logic ‘0’ and a low resistance state with a logic ‘1’. The actual state and thus the stored information can be read out by a resistance readout or measuring the leakage current.

In accordance with another embodiment of the present invention, the microelectronic device includes a single capacitor-like structure with only one pair of electrodes for operating it, i.e. to read from, to write into or to erase without a transistor arrangement being necessarily coupled with a capacitor used in prior art to perform the operating functions of a prior art DRAM cell. One terminal of such a cell is connected to ground and the other is used for writing, erasing or just reading. Thus, RAM cells can be constructed to use considerably less space on a chip and considerably less manufacturing steps.

Further, the material has a remarkable high retention time without the requirement of power signals for refreshing it, and can thus be used as a non-volatile memory. Thus, following advantages can be achieved: full time is available for read and write processes because the refresh cycles and therefore the refresh circuitry are not required, and, a data storage security is increased as a loss of power supply does not imply a loss of stored data.

In accordance with an embodiment of the invention, the memory cell can be operated in either a voltage controlled or in a current controlled regime, i.e. information can be stored by applying voltage pulses or by applying current pulses. In both the cases, the information can be read by sensing voltage or current. The read-out operation is non-destructive and does not change the stored information, i.e. multiple read-out operations of the information without rewriting of data are possible.

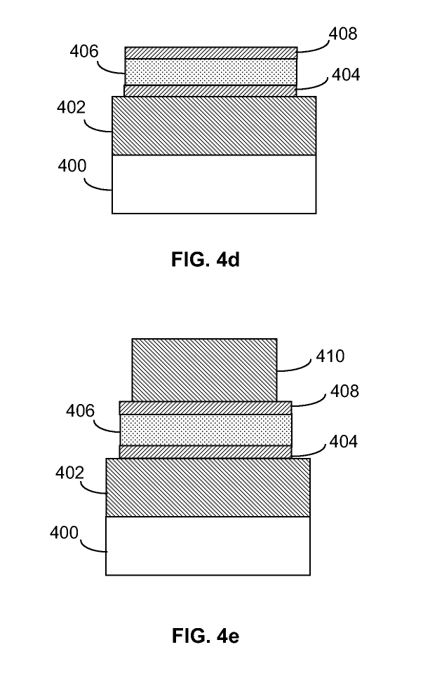

FIGS. 4a to 4e illustrate different cross-sections of a microelectronic device during a fabricating process according to an embodiment of the present invention. The microelectronic device exhibiting bi-stable resistance can be easily fabricated using known techniques. First, referring to FIG. 4a, a substrate 400 is provided. A second electrode 402 is formed on substrate 400. The fabrication of second electrode 402 is achieved by sputtering, evaporation, chemical vapor deposition (CVD) or any other suitable deposition techniques onto substrate 400, such as a silicon wafer. In accordance with an embodiment of the present invention, second electrode 402 can be formed using alloys. In case of an alloy-based electrode 402, for example Pt—Nb, co-sputtering of the alloys in the proper proportions, such as 0.01-10 percent Nb, can be performed. In accordance with another embodiment of the present invention, alloy-based electrode 402 can be formed via co-evaporation of the alloys. A person skilled in the art will appreciate that other known co-deposition techniques can be used for fabrication of second electrode 402.

Next, a first programmable resistance layer 404 is deposited as shown in FIG. 4b. Preferably, programmable resistance layer 404 such as a transition-metal oxide is formed by sputtering or vapor deposition. In accordance with an embodiment of the present invention, programmable resistance layer 404 can be doped with an impurity, for example, Nb-doped SrTiO3. In case of doped programmable resistance layer 404, co-sputtering of an impurity in the proper proportions, such as 0.01-10 percent Nb, can be done. In accordance with another embodiment of the present invention, the impurity (dopant) can be deposited on second electrode 402 and migrated into programmable resistance layer 404 by diffusion. In accordance with yet another embodiment of the present invention, ion implantation technique can be used to form doped programmable resistance layer 404. A person skilled in the art will appreciate that other techniques including exposure to reactive gases can be used to form programmable resistance layer 404.

Next, an intermediate layer 406 is deposited on programmable resistance layer 404 as shown in FIG. 4c. Intermediate layer 406 can be doped via diffusion or ion implantation techniques. Various other techniques such as exposure to reactive gases can be used to form intermediate layer 406. Intermediate layer 406 can be formed using reduced strontium titanium oxide (SrTiO_{3-δ}), niobium-doped strontium titanium oxide (Nb-doped SrTiO₃), lanthanum titanium oxide (LaTiO_{3+δ}), lanthanum strontium titanium oxide ((La, Sr)TiO₃), tin oxide (SnO₂), and indium tin oxide (ITO).

Next, a second programmable resistance layer 408 is fabricated on intermediate layer 406 as shown in FIG. 4d. In accordance with an embodiment of the present invention, an oxygen plasma treatment of intermediate layer 406 forms second programmable resistance layer 408 on a surface of intermediate layer 406. Various other techniques including sputter deposition can be used to form second programmable resistance layer 408. Moreover, second programmable resistance layer 408 can be doped via diffusion, ion-implantation or co-sputtering techniques.

Programmable resistance layers 404 and 408 can be made from chromium-doped strontium titanium oxide (Cr-doped SrTiO₃), strontium titanium oxide (SrTiO₃), barium titanium oxide (BaTiO₃), strontium barium titanium oxide ((Sr, Ba)TiO₃), praseodymium manganese oxide (PrMnO₃), calcium manganese oxide (CaMnO₃), praseodymium calcium manganese oxide ((Pr, Ca)MnO₃), strontium zirconium oxide (SrZrO₃), nickel oxide (NiO), titanium oxide (TiO₂), and tantalum oxide (Ta₂O₅), or other transition-metal oxides. The transition metal oxides can be doped preferentially with chromium, manganese, or vanadium. The doping concentration of programmable resistance layers 404 and 408 can be different. However, it will be obvious to a person skilled in the art that same doping concentration will also work. The previously mentioned embodiment illustrates the present invention with the help of two programmable resistance layers 404 and 408. The present invention also includes a microelectronic device with a stack of programmable resistance layers such that each programmable resistance layer is specialized for a particular application.

Finally, a first electrode 410 is deposited on top of programmable resistance layer 408 by a variety of deposition techniques such as evaporation, CVD or sputtering. In case of an alloy first electrode 410, such as Pt—Nb, co-sputtering of these materials in the proper proportions, such as 0.01-10 percent Nb, will be sufficient to prepare first electrode 410. Another technique is to use co-evaporation of the alloy constituents or any other suitable co-deposition technique.

After the deposition of various layers, a heating step may be required for thermal diffusion of the dopants.

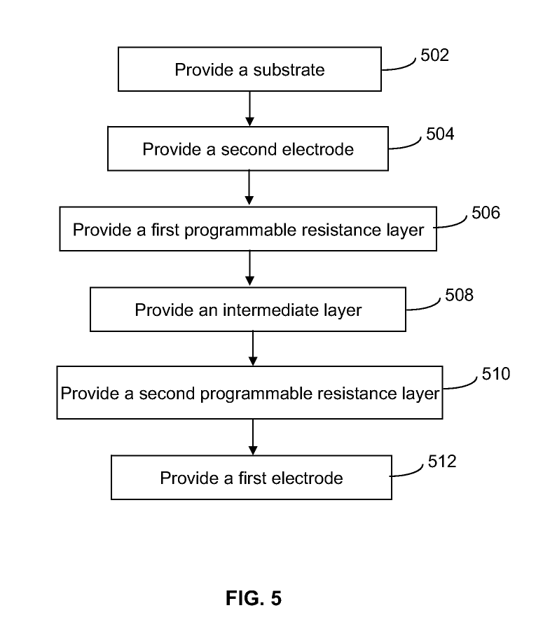

FIG. 5 illustrates a flowchart showing a method of fabricating a microelectronic device in conjunction with FIGS. 4a to 4e in accordance with an embodiment of the present invention. At step 502, a substrate is provided. At step 504, a second electrode is formed on the substrate as shown and detailed in FIG. 4a. A first programmable resistance layer is provided on the second electrode at step 506 as shown and detailed in FIG. 4b. An intermediate layer is provided on top of first programmable resistance layer at step 508 as shown and detailed in FIG. 4c. Next, a second programmable resistance layer is provided on top of the intermediate layer at step 510 as shown and detailed in FIG. 4d. Although the flowchart is described using the first and second programmable resistance layers with the intermediate layer, the present invention can be practiced using multiple programmable resistance layers with at least one intermediate layer. Finally, a second electrode is provided on top of the second programmable resistance layer at step 512 as shown and detailed in FIG. 4e. The resistivity of the intermediate layer is between the low resistivity of the first and second electrodes and the high resistivity of the programmable resistance layers.

In the aforesaid description, specific embodiments of the present invention have been described by way of examples with reference to the accompanying figures and drawings. One of ordinary skill in the art will appreciate that various modifications and changes can be made to the embodiments without departing from the scope of the present invention as set forth in the claims below. Accordingly, the specification and figures are to be regarded in an illustrative rather than a restrictive sense, and all such modifications are intended to be included within the scope of present invention.

We claim:

1. A microelectronic device comprising:
a first electrode;
a second electrode facing the first electrode;
a plurality of programmable resistance layers placed between the first electrode and the second electrode; and
at least one intermediate layer wherein the intermediate layer is placed between two programmable resistance layers, wherein the resistivity of the intermediate layer is between the low resistivity of the first and second electrodes and the high resistivity of the programmable resistance layers.

2. The device according to claim 1, wherein at least one of the composition and the doping concentration of the material used for at least one programmable resistance layer is different from the other programmable resistance layers.

3. The device according to claim 1, wherein the material of the programmable resistance layers comprises a transition-metal oxide.

4. The device according to claim 3, wherein the transition-metal oxide is doped with at least one of chromium, manganese, and vanadium.

5. The device according to claim 3, wherein the transition-metal oxide is selected from a group consisting of chromium-doped strontium titanium oxide (Cr-doped SrTiO₃), strontium titanium oxide (SrTiO₃), barium titanium oxide (BaTiO₃), strontium barium titanium oxide ((Sr, Ba)TiO₃), praseodymium manganese oxide (PrMnO₃), calcium manganese oxide (CaMnO₃), praseodymium calcium manganese oxide ((Pr, Ca)MnO₃), strontium zirconium oxide (SrZrO₃), nickel oxide (NiO), titanium oxide (TiO₂), and tantalum oxide (Ta₂O₅).

6. The device according to claim 1, wherein the resistivity of at least one programmable resistance layers is at least 10⁵ Ohm cm.

7. The device according to claim 1, wherein the material of the intermediate layers comprise an electrically conducting material selected from a group consisting of reduced strontium titanium oxide (SrTiO_{3-δ}), niobium-doped strontium titanium oxide (Nb-doped SrTiO₃), lanthanum titanium oxide (LaTiO_{3+δ}), lanthanum strontium titanium oxide ((La, Sr)TiO₃), tin oxide (SnO₂), indium tin oxide (ITO), other transition-metal oxides, TiN, AlN and other nitrides.

8. The device according to claim 1, wherein the resistivity of the intermediate layers varies between 10⁵ Ohm cm and 0.1 mOhm cm.

9. The device according to claim 1, wherein the microelectronic device is used as memory.

10. A method of fabricating a microelectronic device comprising:
providing a substrate;
forming a second electrode on the substrate;
providing a plurality of programmable resistance layers wherein a first programmable resistance layer is provided on the second electrode;
providing at least one intermediate layer wherein the intermediate layer is provided between two programmable resistance layers; and
forming a first electrode on top of the programmable resistance layers,
wherein the resistivity of the intermediate layer is between the low resistivity of the first and second electrodes and the high resistivity of the programmable resistance layers.

11. The method according to claim 10, further comprising doping the programmable resistance layers, wherein one of the composition and the doping concentration of the material used for at least one programmable resistance layer is different from the other programmable resistance layers.

12. The method according to claim 11, wherein at least one of doping the programmable resistance layers comprises a technique selected from a group consisting of co-deposition, diffusion, ion-implantation, exposure to reactive gases technique, and heating the substrate for facilitating thermal diffusion of dopants.

13. The method according to claim 10, further comprising at least one of doping and chemical modification of the material of the intermediate layer.

14. The method according to claim 13, wherein at least one of doping and chemical modification comprises a technique selected from a group consisting of co-deposition, diffusion, ion-implantation, exposure to reactive gases technique, and heating the substrate for facilitating thermal diffusion of dopants.

15. A programmable resistor comprising:
a first electrode;
a second electrode facing the first electrode;
a first and second programmable resistance layers placed between the first electrode and the second electrode; and
an intermediate layer placed between the first and second programmable resistance layers, wherein the resistivity of the intermediate layer is between the low resistivity of the first and second electrodes and the high resistivity of the programmable resistance layers.

16. The programmable resistor according to claim 15, wherein the material of the programmable resistance layers comprises a transition-metal oxide.

17. The programmable resistor according to claim 16, wherein the transition-metal oxide is doped with at least one of chromium, manganese, and vanadium.

18. The programmable resistor according to claim 16, wherein the transition-metal oxide is selected from a group consisting of chromium-doped strontium titanium oxide (Cr-doped SrTiO₃), strontium titanium oxide (SrTiO₃), barium titanium oxide (BaTiO₃), strontium barium titanium oxide ((Sr, Ba)TiO₃), praseodymium manganese oxide (PrMnO₃), calcium manganese oxide (CaMnO₃), praseodymium calcium manganese oxide ((Pr, Ca)MnO₃), strontium zirconium oxide (SrZrO₃), nickel oxide (NiO), titanium oxide (TiO₂), and tantalum oxide (Ta₂O₅).

19. The programmable resistor according to claim 15, wherein the material of the intermediate layer comprises an electrically conducting material selected from a group consisting of reduced strontium titanium oxide (SrTiO_{3-δ}), niobium-doped strontium titanium oxide (Nb-doped SrTiO₃), lanthanum titanium oxide (LaTiO_{3+δ}), lanthanum strontium titanium oxide ((La, Sr)TiO₃), tin oxide (SnO₂), indium tin oxide (ITO), other transition-metal oxides, TiN, AlN and other nitrides.

20. A microelectronic device prepared by a process comprising:
forming a second electrode on a substrate;
providing a plurality of programmable resistance layers wherein a first programmable resistance layer is provided on the second electrode;
providing at least one intermediate layer wherein the intermediate layer is provided between two programmable resistance layers; and
forming a first electrode on top of the programmable resistance layers, wherein the resistivity of the intermediate layer is between the low resistivity of the first and second electrodes and the high resistivity of the programmable resistance layers.
